(19) United States
(12) Patent Application Publication
(10) Pub. No.: US 2009/0321705 A1
(43) Pub. Date: Dec. 31, 2009

(54) PHASE CHANGE MEMORY DEVICE AND METHOD FOR MANUFACTURING THE SAME

(75) Inventors: Min Yong Lee, Ichon (KR); Su Jin Chae, Ichon (KR); Keum Bum Lee, Ichon (KR); Dong Ryeol Lee, Ichon (KR); Hyung Suk Lee, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: Hynix Semiconductor, Inc., Ichon (KR)

(21) Appl. No.: 12/256,385

(22) Filed: Oct. 22, 2008

(30) Foreign Application Priority Data
Jun. 30, 2008 (KR) 10-2008-0062625

(51) Int. Cl. H01L 47/00; H01L 21/00

(52) U.S. Cl. 257/2; 438/102; 257/E47.001; 257/E21.001

(57) ABSTRACT

A phase change memory device includes a semiconductor substrate, a first conductive pattern formed on the semiconductor substrate, a second conductive pattern contacting an upper surface of the first conductive pattern and having a diameter less than a diameter of the first conductive pattern, and a phase change material layer contacting the second conductive pattern.

### CROSS-REFERENCES TO RELATED APPLICATION

The present application claims priority under 35 U.S.C. §119(a) to Korean application number 10-2008-0062625, filed on Jun. 30, 2008, in the Korean Intellectual Property Office, which is incorporated herein by reference in its entirety as if set forth in full.

### BACKGROUND

1. Technical Field

The embodiments described herein relate to a memory device and, more particularly, to a phase change memory device and a method for manufacturing the same.

2. Related Art

Generally, phase change random access memory (PRAM) devices are memory devices that read and write information by phase changes of a phase change material having high resistance in an amorphous phase and low resistance in a crystalline phase. The PRAM devices are advantageous in that they have relatively high operation speeds and high integration levels.

In the PRAM devices, the phase changing material is a material that changes phases between a crystalline phase and an amorphous phase depending upon a temperature of the phase change material. In the crystalline phase, the phase change material has low resistance and regular atomic arrangement, as compared to the amorphous phase. For example, the phase change material is a Chalcogenide that includes a compound made of germanium (Ge), antimony (Sb), and tellurium (Te), which is commonly referred to as GST.

In a PRAM device, as current is supplied through bottom electrodes, a temperature of a phase change material layer is changed due to Joule heating by the current application. Accordingly, by appropriately changing the applied current, the crystal structure of the phase change material layer can be changed between the crystalline state and the amorphous state. For example, a phase change occurs by the Joule heat between the crystalline state, i.e., a set state, having low resistance and the amorphous state, i.e., a reset state, having high resistance. In read and write operational modes, the information stored in a phase change memory cell is set state data (0) or reset state data (1) is determined by sensing the current flowing through a phase change layer. Thus, the structure of a bottom electrode contact (BEC), which serves as a heating element for heating a phase change material, is important. The amount of current generated during a reset operational mode of the PRAM device determines the operational lifetime, the sensing margin, and the shrinkage of the PRAM device.

In the PRAM device, when contact resistance between the BEC and an underlying switching element is low, excellent electrical characteristics can be obtained. Conversely, the operational characteristics of the PRAM device can be improved when a phase change material layer formed on the BEC has a minimum volume that undergoes a phase change between the crystalline state and the amorphous state. Accordingly, when the contact resistance between the phase change material layer and the BEC is high, the reset current can be decreased. Thus, a cylindrical-shaped BEC is used to minimize a contact area between the BEC and the phase change material layer while maintaining the contact area between the BEC and the switching element.

FIGS. 1a and 1b are cross sectional views of conventional cylindrical-shaped BECs of a phase change memory device. In FIG. 1a, an interlayer dielectric 103 is formed on a semiconductor substrate 101, which is formed having switching elements (not shown), such as PN diodes, formed therein. After defining contact holes to expose the switching elements, a conductive material layer 105 is formed on the bottom and the sidewalls of the contact holes, and a dielectric material layer 107 is formed within the contact holes. The conductive material layer 105 functions as the cylindrical-shaped BECs, which serve as heating elements for heating a phase change material layer formed in a subsequent process. As shown in FIG. 1b, the BEC has a cylinder-shaped structure including the dielectric material layer 107 filled therein.

In the case that the BEC is formed to have the cylinder-shaped structure, in order to minimize the contact area between the phase change material layer and the BEC, the contact holes must be defined to have a minimum size. However, since there is a limit in reducing a mask sizing for defining the contact holes, it is difficult to minimize the reset current for the PRAM device. Thus, a BEC having a column-shaped structure has been suggested.

FIGS. 2a and 2b are cross sectional views of conventional columnar-shaped BECs of a phase change memory device. In FIG. 2a, an interlayer dielectric 103 is formed on a semiconductor substrate 101, which is formed having an underlying structure including switching elements (not shown). After defining contact holes to expose the switching elements, dielectric material spacers 109 are formed on the sidewalls of the contact holes, and a conductive material layer 111 is formed within the contact holes. In FIG. 2b, the BEC has a columnar-shaped structure that is surrounded by the dielectric material spacer 109.

The columnar-shaped structure of the BEC is disadvantageous for increasing the contact resistance between the BEC and a phase change material layer. Nevertheless, because the contact resistance between the BEC and the switching element also increases, the operating current of the switching element decreases and the operational characteristics of the phase change memory device are likely to deteriorate.

### SUMMARY

A phase change memory device capable of reducing contact resistance between bottom electrode contacts and switching elements and capable of increasing contact resistance between the bottom electrode contacts and a phase change material layer, and a method for manufacturing the same are described herein.

In one aspect, a phase change memory device includes a semiconductor substrate, a first conductive pattern formed on the semiconductor substrate, a second conductive pattern contacting an upper surface of the first conductive pattern and having a diameter less than a diameter of the first conductive pattern, and a phase change material layer contacting the second conductive pattern.

In another aspect, a phase change memory device includes a semiconductor substrate, a first conductive pattern formed on the semiconductor substrate, a cylindrical second conductive pattern contacting the first conductive pattern, having a diameter less than a diameter of the first conductive pattern, and filled therein with a dielectric material, and a phase change material layer contacting the second conductive pattern.

In another aspect, a method for manufacturing a phase change memory device includes forming a first conductive pattern having a first diameter on a semiconductor substrate that includes an underlying structure, and forming a second conductive pattern on the first conductive pattern, wherein a diameter of the second conductive pattern is less than the diameter of the first conductive pattern.

In another aspect, a method for manufacturing a phase change memory device includes forming a first conductive pattern having a first diameter on a semiconductor substrate that includes an underlying structure, and forming a cylindrical second conductive pattern having a dielectric material filled therein on the first conductive pattern, wherein a diameter of the second conductive pattern is less than the first diameter of the first conductive pattern.

These and other features, aspects, and embodiments are described below in the section “Detailed Description.”

### BRIEF DESCRIPTION OF THE DRAWINGS

Features, aspects, and embodiments are described in conjunction with the attached drawings, in which:

FIGS. 1a and 1b are cross sectional views of conventional cylindrical-shaped BECs of a phase change memory device;

FIGS. 2a and 2b are cross sectional views of conventional columnar-shaped BECs of a phase change memory device;

FIGS. 3a to 3g are cross sectional views of an exemplary method for manufacturing a phase change memory device in accordance with one embodiment;

FIG. 4 is a cross sectional view of an exemplary phase change memory device in accordance with another embodiment;

FIG. 5 is a cross sectional view of another exemplary phase change memory device in accordance with another embodiment; and

FIG. 6 is a cross sectional view of another exemplary phase change memory device in accordance with another embodiment.

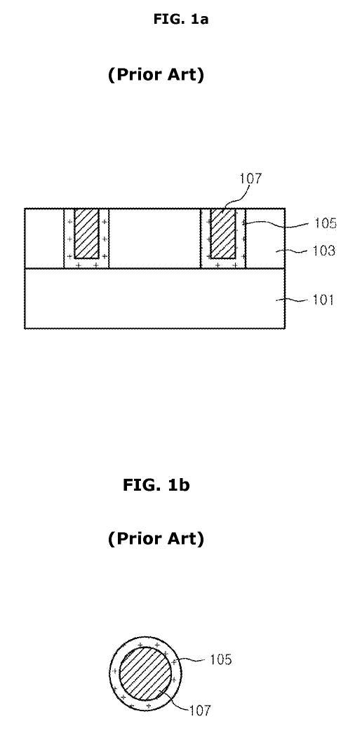

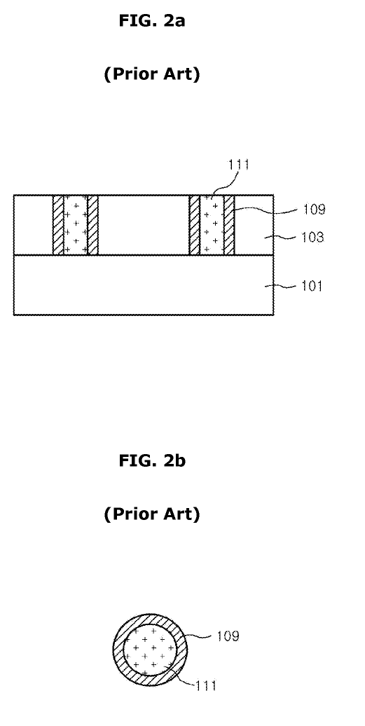

### DETAILED DESCRIPTION

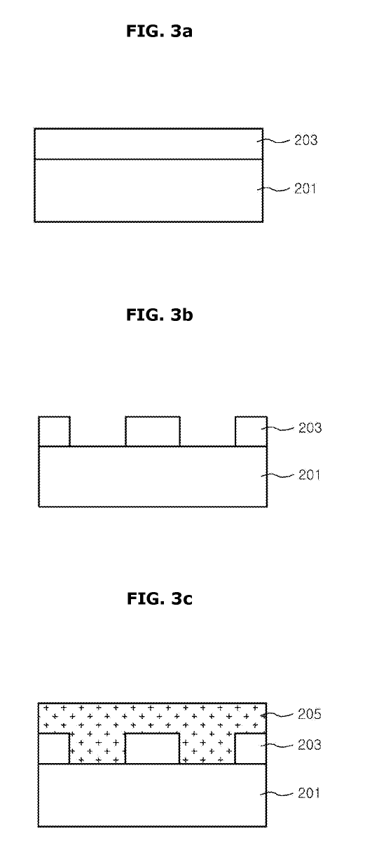

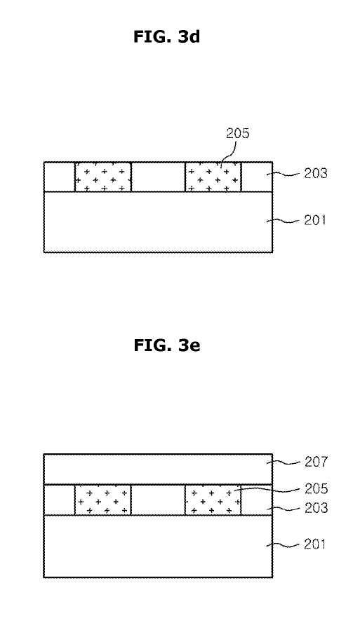

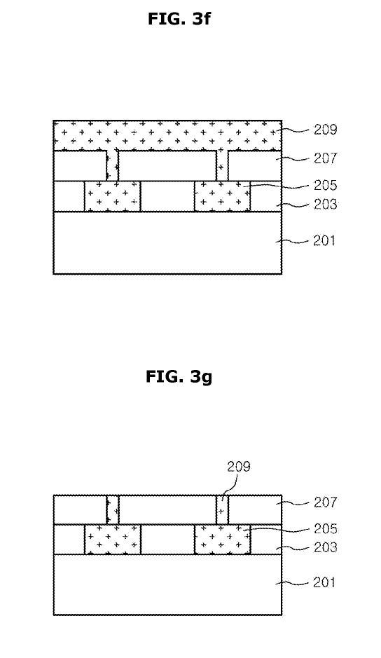

FIGS. 3a to 3g are cross sectional views of an exemplary method for manufacturing a phase change memory device in accordance with one embodiment. In FIG. 3a, a first interlayer dielectric 203 can be formed on a semiconductor substrate 201. Although not shown, the semiconductor substrate can include underlying structures, such as a plurality of switching elements.

In FIG. 3b, a plurality of first contact holes can be defined to expose corresponding ones of the switching elements. For example, regions of the first interlayer dielectric 203 can be patterned corresponding to subsequently formed BECs. For example, the first interlayer dielectric 203 can be formed to a relatively uniform thickness within a range of about 200 Å to about 1,200 Å, and a diameter of each of the plurality of first contact holes can be within a range of about 80 nm to about 90 nm.

In FIG. 3c, a first conductive layer 205 can be formed on the patterned first interlayer dielectric 203, within the plurality of first contact holes, and upon the semiconductor substrate 201. Accordingly, a first conductive pattern can be formed to contact corresponding ones of the switching elements within the semiconductor substrate 201. Here, the first conductive patterns can be configured to have relatively wide contact areas with regard to the switching element.

In FIG. 3d, planarization can be used such that portions of the first conductive layer 205 are individually filled within each of the plurality of first contact holes. Accordingly, the portions of the first conductive layer 205 filled within each of the plurality of first contact holes can serve as first conductive patterns 205 that contact the switching elements of the semiconductor substrate 201.

In FIG. 3e, a second interlayer dielectric 207 can be formed on the first conductive patterns 205 and the patterned first dielectric 203. For example, the second interlayer dielectric 207 can be formed to a relatively uniform thickness within a range of about 200 Å to about 1,200 Å.

In FIG. 3f, after defining a plurality of second contact holes by patterning the second interlayer dielectric 207 to expose upper surface portions of the first conductive layer 205, a second conductive layer 209 can be formed on the patterned second interlayer dielectric 207 and within the plurality of second contact holes. Here, a diameter of each of the plurality of second contact holes can be less than a diameter of each of the plurality of first contact holes. For example, the diameter of each of the plurality of second contact holes can be within a range of about 50 nm to about 80 nm.

In FIG. 3g, planarization can be used such that portions of the second conductive layer 209 such that portions of the second conductive layer 209 are individually filled within each of the plurality of second contact holes. Accordingly, the portions of the second conductive layer 209 filled within each of the plurality of second contact holes can serve as second conductive patterns 209 that contact the first conductive patterns 205.

Here, the first and second conductive layers 205 and 209 can be made of a material, or materials. For example, the first and second conductive layers 205 and 209 can be made from materials including titanium nitride (TiN), titanium/titanium nitride (Ti/TiN), titanium aluminum nitride (TiAlN), tungsten nitride (WN), titanium tungsten (TiW), and tantalum nitride (TaN).

Although not shown, in subsequent processing, a phase change material layer can be formed on resultant structure, as described above, including the second conductive patterns 209. Accordingly, wide contact areas can be formed between the first conductive patterns 205 and the switching elements within the semiconductor substrate 201. In addition, the contact area between the second conductive patterns 209 and the phase change material layer (not shown) can be minimized. Thus, a reset current of the phase change material can be minimized, and the driving current of the switching elements can be increased.

While the first and second conductive patterns 205 and 209 are shown to include two layers, another embodiment can includes additional numbers of layers. For example, conductive patterns including three or more layers can be used.

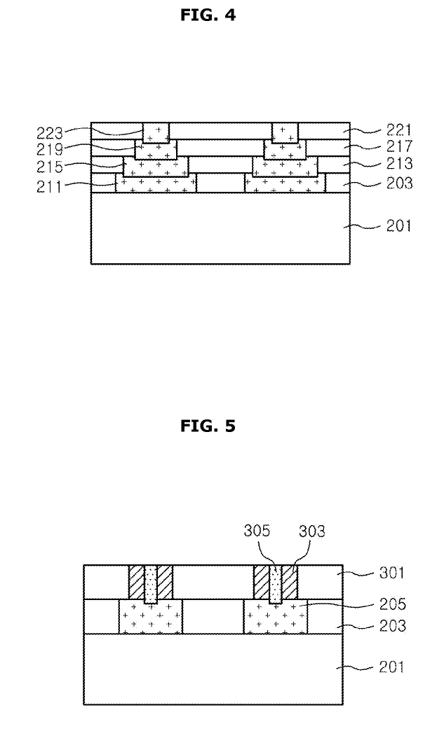

FIG. 4 is a cross sectional view of an exemplary phase change memory device in accordance with another embodiment. In FIG. 4, each conductive pattern structure can operate as a BEC and can include a first conductive pattern 211, a second conductive pattern 215, a third conductive pattern 219, and a fourth conductive pattern 223. Here, sizes of the respective conductive patterns can be controlled such that the diameters thereof gradually decrease along a direction from the semiconductor substrate 201 upward to a top-most one of the conductive patterns.

An exemplary method for manufacturing a phase change memory device configured in FIG. 4 will now be described. In FIG. 4, the semiconductor substrate 201 can include a plurality of switching elements (not shown), and a phase change material layer (not shown) formed overlying the fourth conductive pattern 223.

A first interlayer dielectric 203 can be formed on a semiconductor substrate 201, a plurality of first contact holes can be defined within the first interlayer dielectric 203, and a plurality of first conductive patterns 211 can be formed. Next, a second interlayer dielectric 213 can be formed on the first interlayer dielectric 203 and the plurality of first conductive patterns 211, and a plurality of second contact holes can be defined within the second interlayer dielectric 213 to expose upper surface regions of each of the first conductive patterns 211. Here, each of the plurality of second contact holes can be defined to have a diameter less than a diameter of each of the plurality of first contact holes. Then, a plurality of second conductive patterns 215 can be formed within the plurality of second contact holes.

Next, a third interlayer dielectric 217 can be formed on the second interlayer dielectric 203 and the plurality of second conductive patterns 215, and a plurality of third contact holes, each having a diameter less than the diameter of each of the plurality of second contact holes, can be defined within the third interlayer dielectric 217 to expose upper surface portions of each of the plurality of second conductive patterns 215 Then, a plurality of third conductive patterns 219 can be formed within the plurality of third contact holes.

Next, a fourth interlayer dielectric 221 can be formed on the third interlayer dielectric 217 and the plurality of third conductive patterns 219, and a plurality of fourth contact holes, each having a diameter less than the diameter of each of the plurality of third contact holes, can be defined within the fourth interlayer dielectric 221 to expose upper surface regions of each of the plurality of third conductive patterns 219. Then, a plurality of fourth conductive patterns 223 can be formed within the plurality of fourth contact holes.

Here, the diameters of the first, second, third, and fourth contact holes can be, respectively, within ranges of about 80 nm to about 90 nm, about 70 nm to about 80 nm, about 60 nm to about 70 nm, and about 50 nm to about 60 nm. In addition, each of the first, second, third, and fourth interlayer dielectrics 203, 213, 217, and 221 can be formed to a relatively uniform thickness within a range of about 200 Å to about 1,200 Å.

The first, second, third, and fourth conductive patterns 211, 215, 219, and 223 can include a material, or materials, selected from a group including titanium nitride (TiN), titanium/titanium nitride (Ti/TiN), titanium aluminum nitride (TiAlN), tungsten nitride (WN), titanium tungsten (TiW), and tantalum nitride (TaN), for example.

In FIG. 4, a phase change memory device can include electrical interconnection structures, each having a pyramidal-stepped configuration. As a result, contact areas between switching elements of the substrate and BECs, and contact areas between a phase change material layer and the BECs can be minimized.

As shown in FIG. 4, an over-etching process for defining the respective contact holes can be performed. Accordingly, the contact between the conductive patterns can be improved. For example, each of the plurality of second conductive patterns 215 can be disposed within corresponding recessed upper surfaces of the first conductive patterns 211. Similarly, each of the plurality of third conductive patterns 219 can be disposed within corresponding recessed upper surfaces of the second conductive patterns 215. Likewise, each of the plurality of fourth conductive patterns 223 can be disposed within corresponding recessed upper surfaces of the third conductive patterns 219.

When forming the BECs having the multi-layered conductive pattern structure of FIG. 4, for example, the conductive patterns of the respective layers do not necessarily have to be of the same cross sectional shape.

FIG. 5 is a cross sectional view of another exemplary phase change memory device in accordance with another embodiment. In FIG. 5, a first interlayer dielectric 203 can be selectively formed on a semiconductor substrate 201. Although not shown, a plurality of switching elements can be provided within the semiconductor substrate 201. Then, a conductive layer can be processed to form a plurality of first conductive patterns 205 within the first interlayer dielectric 203. Here, each of the first conductive patterns 205 can have a diameter within a range of about 80 nm to about 90 nm.

Next, a plurality of second conductive patterns 305, each contacting corresponding ones of the plurality of first conductive patterns 205, can be formed having columnar shapes. For example, a second interlayer dielectric 301 can be formed on the first interlayer dielectric 203 and the plurality of first conductive patterns 205. Then, a plurality of contact holes can be formed within the second interlayer dielectric 301 by patterning, for example, to expose upper surface portions of the plurality of first conductive patterns 205. Next, dielectric material spacers 303 can be selectively formed along sidewalls of each of the plurality of contact holes. Finally, a second conductive layer can be formed over the second interlayer dielectric 301 and within an opening between the dielectric material spacers 303 within each of the plurality of contact holes, and subsequently patterned to form the plurality of second conductive patterns 305 within each of the plurality of contact holes. Accordingly, each of the plurality of second conductive patterns 305 can be columnar-shaped. In addition, each of the plurality of second conductive patterns 305 can have portions that extend into upper surface regions of the first conductive patterns 205 to improve electrical contact between the first and second conductive patterns 205 and 305. For example, during an etching process for forming the plurality of first conductive patterns 205, the upper surface regions of each of the plurality of first conductive patterns 205 can be over-etched to form surface recesses. Thus, when the second conductive layer is subsequently formed, lower portions of the second conductive patterns 305 can extend into the surface recesses of the plurality of first conductive patterns 205.

A diameter of the opening between the dielectric material spacers 303 within the plurality of contact holes within the second interlayer dielectric 301, and correspondingly, the diameter of each of the plurality of second conductive patterns 305 can be within a range of about 50 nm to about 80 nm, for example. In addition, the first and second conductive layers 205 and 305 can be formed of a material, or materials, selected from a group including titanium nitride (TiN), titanium/titanium nitride (Ti/TiN), titanium aluminum nitride (TiAlN), tungsten nitride (WN), titanium tungsten (TiW), and tantalum nitride (TaN), for example.

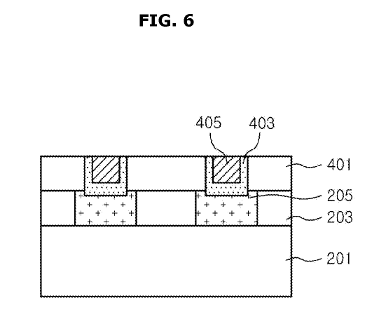

FIG. 6 is a cross sectional view of another exemplary phase change memory device in accordance with another embodiment. In FIG. 6, a first interlayer dielectric 203 can be selectively formed on a semiconductor substrate 201. Then, a conductive layer can be processed to form a plurality of first conductive patterns 205 within the first interlayer dielectric 203. Here, each of the first conductive patterns 205 can have a diameter within a range of about 80 nm to about 90 nm.

Next, a second interlayer dielectric 401 can be formed on the first interlayer dielectric 203 and the plurality of first conductive patterns 205, and a plurality of contact holes can be formed by patterning the second interlayer dielectric 401 to expose upper surfaces of each of the first conductive patterns 205.

Then, a second conductive layer can be selectively formed on the bottom and the sidewalls of each of the plurality of contact holes to form a plurality of second conductive patterns 403. Next, a dielectric material layer 405 can be filled into the contact holes. Specifically, the dielectric material layer 405 can fill a recess of each of the plurality of second conductive patterns 403.

As shown in FIG. 6, an over-etching process for defining the respective contact holes within the second interlayer dielectric 401 can be performed. Accordingly, the contact between the first and second conductive patterns 205 and 403 can be improved, wherein each of the plurality of second conductive patterns 403 can be disposed within corresponding recessed upper surfaces of the first conductive patterns 205. For example, during an etching process for forming the plurality of first conductive patterns 205, the upper surface regions of each of the plurality of first conductive patterns 205 can be over-etched to form surface recesses. Thus, when the second conductive layer is subsequently formed, lower portions of the second conductive patterns 403 can extend into the surface recesses of the plurality of first conductive patterns 205.

Here, a diameter of each of the plurality of first conductive patterns 205 can be within a range of about 80 nm to about 90 nm, for example. In addition, and a diameter of each of the plurality of contact holes within the second interlayer dielectric 401 for forming the second conductive patterns 403 can be within a range of about 50 nm to about 80 nm, for example.

In FIG. 6, although not shown, a plurality of switching elements can be provided within the semiconductor substrate 201, and a phase change material layer can be formed overlying the second interlayer dielectric 401. Accordingly, the contact structure shown in FIG. 6 provides an electrical pathway from the switching elements within the semiconductor substrate 201 to the phase change material layer of the phase change memory device.

In FIG. 6, the first and second conductive layers 205 and 403 can be made of a material, or materials, selected from a group including titanium nitride (TiN), titanium/titanium nitride (Ti/TiN), titanium aluminum nitride (TiAlN), tungsten nitride (WN), titanium tungsten (TiW), and tantalum nitride (TaN), for example.

According to the embodiments described above, while a wide contact area between a BEC and a switching element can be maintained, a contact area between the BEC and a phase change material layer can be minimized, thereby reducing a reset current. Thus, the operating current of a phase change memory device can be maximized even by supplying a relatively low driving current, whereby a high integration level can be accomplished and the phase change memory device can operate stably.

In addition, since the contact area between the BEC and the switching element and the contact area between the BEC and the phase change material layer can be separately controlled, the reset current can be reduced by increasing contact resistance at the interface between the BEC and the phase change material layer. Moreover, driving current can be increased by reducing contact resistance at the interface between the BEC and the switching element.

Since the phase change memory device can operate with low current consumption, even without increasing the size of the phase change memory device, manufacture of a phase change memory device that can be incorporated into portable communication devices, such as mobile phones, PDAs, and mobile PCs, can be accomplished.

While certain embodiments have been described above, it will be understood that the embodiments described are by way of example only. Accordingly, the device and method described herein should not be limited based on the described embodiments. Rather, the devices and methods described herein should only be limited in light of the claims that follow when taken in conjunction with the above description and accompanying drawings.

What is claimed is:

1. A phase change memory device, comprising:
a semiconductor substrate;
a first conductive pattern formed on the semiconductor substrate;
a second conductive pattern contacting an upper surface of the first conductive pattern and having a diameter less than a diameter of the first conductive pattern; and
a phase change material layer contacting the second conductive pattern.

2. The phase change memory device according to claim 1, wherein the second conductive pattern has a stack structure in which a diameter of an underlying conductive pattern is greater than a diameter of an overlying conductive pattern.

3. The phase change memory device according to claim 1, wherein a lower surface of the second conductive pattern is disposed within a recess formed within the upper surface of the first conductive pattern.

4. A phase change memory device, comprising:
a semiconductor substrate;
a first conductive pattern formed on the semiconductor substrate;
a cylindrical second conductive pattern contacting the first conductive pattern, having a diameter less than a diameter of the first conductive pattern, and filled therein with a dielectric material; and
a phase change material layer contacting the second conductive pattern.

5. The phase change memory device according to claim 4, further comprising:
an interlayer dielectric formed along outer sidewalls of the second conductive pattern,
wherein the second conductive pattern is formed along inner sidewalls of the interlayer dielectric and on the first conductive layer.

6. The phase change memory device according to claim 4, wherein a lower surface of the cylindrical second conductive pattern is disposed within a recess formed within the upper surface of the first conductive pattern.

7. A method for manufacturing a phase change memory device, comprising the steps of:
forming a first conductive pattern having a first diameter on a semiconductor substrate that includes an underlying structure; and
forming a second conductive pattern on the first conductive pattern,
wherein a diameter of the second conductive pattern is less than the diameter of the first conductive pattern.

8. The method according to claim 7, wherein the diameter of the first conductive pattern is within a range of 80 nm to 90 nm, and the diameter of the second conductive pattern is within a range of 50 nm to 80 nm.

9. The method according to claim 7, wherein the second conductive pattern is formed to have a stack structure in which a diameter of an underlying conductive pattern is greater than a diameter of an overlying conductive pattern.

10. The method according to claim 9, wherein the second conductive pattern includes first, second, and third conductive layers, the first conductive pattern having a diameter within a range of 80 nm to 90 nm, the first conductive layer contacting the first conductive pattern and having a diameter within a range of 70 nm to 80 nm, the second conductive layer contacting the first conductive layer and having a diameter within a range of 60 nm to 70 nm, and the third conductive layer contacting the second conductive layer and having a diameter within a range of 50 nm to 60 nm.

11. The method according to claim 7, wherein the step of forming the second conductive pattern comprises:
forming an interlayer dielectric on the first conductive pattern;
forming a contact hole by patterning the interlayer dielectric to expose an upper surface of the first conductive layer;
forming a dielectric material spacer on sidewalls of the contact hole, the dielectric material spacer having an opening that exposes a portion of the upper surface of the first conductive layer; and
filling the opening formed with the dielectric material spacer using a conductive material.

12. The method according to claim 7, wherein a lower surface of the second conductive pattern is disposed within a recess formed within an upper surface of the first conductive pattern.

13. A method for manufacturing a phase change memory device, comprising the steps of:
forming a first conductive pattern having a first diameter on a semiconductor substrate that includes an underlying structure; and
forming a cylindrical second conductive pattern having a dielectric material filled therein on the first conductive pattern,
wherein a diameter of the second conductive pattern is less than the first diameter of the first conductive pattern.

14. The method according to claim 13, wherein the step of forming the second conductive pattern comprises:
forming an interlayer dielectric on the first conductive pattern;
forming a contact hole by patterning the interlayer dielectric to expose an upper surface of the first conductive layer;
forming a conductive material layer on a bottom and sidewalls of the contact hole, the conductive material layer forming a recess within the contact hole; and
filling the recess with a dielectric material in the contact hole.

15. The method according to claim 14, wherein the first diameter of the first conductive pattern is within a range of 80 nm to 90 nm, and the diameter of the second conductive pattern is within a range of 50 nm to 80 nm.

16. The method according to claim 13, a lower surface of the cylindrical second conductive pattern is disposed within a recess formed within an upper surface of the first conductive pattern.
